(19) United States
(12) Patent Application Publication
(10) Pub. No.: US 2016/0055891 A1
(43) Pub. Date: Feb. 25, 2016

(54) MAGNETIC MEMORY

(71) Applicants: Hisanori AIKAWA, Seoul (KR); Masayoshi IWAYAMA, Seoul (KR); Akiyuki MURAYAMA, Tokyo (JP); Tatsuya KISHI, Seongnam-si (KR); Sumio IKEGAWA, Tokyo (JP)

(72) Inventors: Hisanori AIKAWA, Seoul (KR); Masayoshi IWAYAMA, Seoul (KR); Akiyuki MURAYAMA, Tokyo (JP); Tatsuya KISHI, Seongnam-si (KR); Sumio IKEGAWA, Tokyo (JP)

(21) Appl. No.: 14/593,678

(22) Filed: Jan. 9, 2015

Related U.S. Application Data
(60) Provisional application No. 62/040,530, filed on Aug. 22, 2014.

(51) Int. Cl. G11C 11/16

(52) U.S. Cl. CPC G11C 11/161; G11C 11/1675

(57) ABSTRACT

According to one embodiment, a magnetic memory includes a memory cell array including magnetoresistive elements, a heater and a temperature sensor provided in the memory cell array, a heater driver which drives the heater, a temperature detector which detects a first temperature sensed by the temperature sensor, and a control circuit which controls the heater driver based on the first temperature.

### CROSS-REFERENCE TO RELATED APPLICATIONS

This application claims the benefit of U.S. Provisional Application No. 62/040,530, filed Aug. 22, 2014, the entire contents of which are incorporated herein by reference.

### FIELD

Embodiments described herein relate generally to a magnetic memory.

### BACKGROUND

A magnetic memory, for example, a magnetoresistive element as a memory cell of a magnetic random access memory, has a basic structure comprising a reference layer having an invariable magnetization direction, a memory layer having a variable magnetization direction, and a nonmagnetic layer (tunnel barrier layer) between the reference layer and the memory layer. When the magnetization direction of the reference layer is the same as that of the memory layer, the magnetoresistive element is in a low-resistance state (parallel state). This state is called, for example, a 0-write state. When the magnetization direction of the reference layer is opposite to that of the memory layer, the magnetoresistive element is in a high-resistance state (anti-parallel state). This state is called, for example, a 1-write state.

For example, when spin-transfer-torque (STT) writing is employed, a write operation which puts the magnetoresistive element into a parallel or anti-parallel state is performed by supplying a write current (spin injection current) to the magnetoresistive element. In terms of low consumption current, the write current necessary for the magnetization inversion of the memory layer is preferably as small as possible. However, this means that the magnetization inversion of the memory layer is easy. In this case, after writing, the magnetization stability (retention) of the memory layer is worse.

Thus, there is a tradeoff between the reduction in the write current necessary for the magnetization inversion of the memory layer and the magnetization stability of the memory layer after writing.

### BRIEF DESCRIPTION OF THE DRAWINGS

FIG. 1 shows an example of a magnetic memory.

FIG. 2 shows a relationship between a write current and a magnetization stability index.

FIG. 3 shows an example of a magnetic memory comprising a plurality of mats.

FIG. 4 is a flowchart showing an example of a temperature control operation.

FIG. 5 is a flowchart showing an example of a write operation.

FIG. 6 shows a relationship between a write temperature and a write operation.

FIG. 7 and FIG. 8 show examples of layouts of a memory cell array.

FIG. 9 and FIG. 10 show circuit examples of a heater cell.

FIG. 11 and FIG. 12 show structural examples of a memory cell.

FIG. 13 shows a structural example of a magnetoresistive element.

FIG. 14 to FIG. 17 show structural examples of the heater cell.

FIG. 18 and FIG. 19 show structural examples of a diode as a temperature sensor.

FIG. 20 shows an example of a memory system in a processor.

### DETAILED DESCRIPTION

In general, according to one embodiment, a magnetic memory comprises: a memory cell array including magnetoresistive elements; a heater and a temperature sensor provided in the memory cell array; a heater driver which drives the heater; a temperature detector which detects a first temperature sensed by the temperature sensor; and a control circuit which controls the heater driver based on the first temperature.

Various embodiments will be described hereinafter with reference to the accompanying drawings.

### 1. Magnetic Memory

### (1) Block Diagram

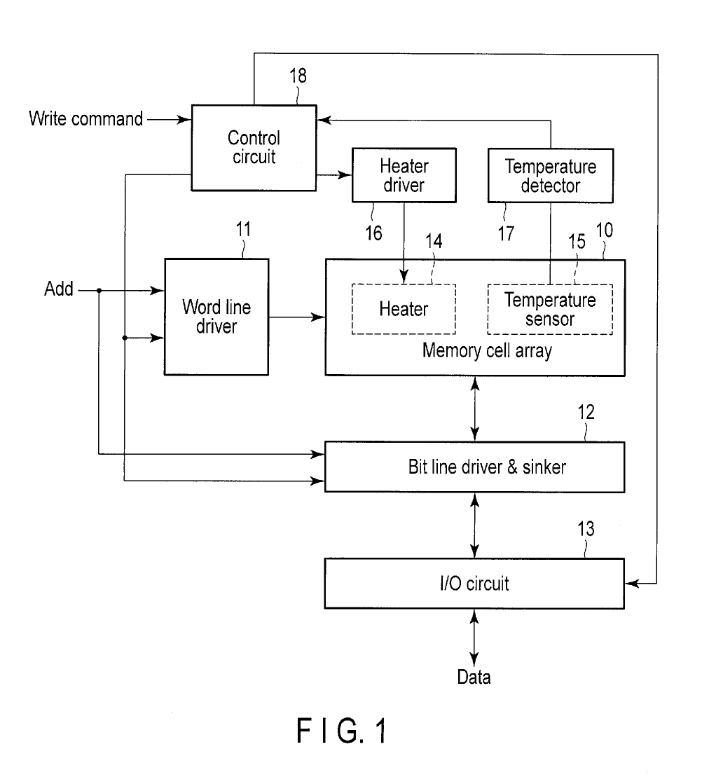

FIG. 1 is a block diagram of a magnetic memory.

A memory cell array 10 comprises an array of a plurality of magnetoresistive elements (memory cells). For example, a word line drive 11 selects one of a plurality of rows in the memory cell array 10 based on an address signal Add in a read/write operation. For example, a bit line driver and sinker 12 selects one of a plurality of columns in the memory cell array 10 based on the address signal Add in the read/write operation.

For example, an input/output (I/O) circuit 13 functions as an interface of data input/output in the read/write operation.

The present embodiment has a feature in which the memory cell array 10 comprises a heater 14 and a temperature sensor 15. For example, the heater 14 includes a resistive element having a resistance between 1 and 100 kΩ. The temperature sensor 15 includes a diode having temperature dependency.

Now, this specification explains reasons that the heater 14 and the temperature sensor 15 are provided in the memory cell array 10 in the present embodiment.

A write current Ic and a magnetization stability index (Δ value) are considered as indexes of characteristics of the magnetic memory. The write current Ic is preferably as small as possible in terms of low consumption current. The Δ value is the ratio of the magnetic anisotropic energy E1 to the thermal energy E2 of a memory layer (E1/E2). The larger the Δ value is, the more stable the magnetization of the memory layer is. Therefore, the Δ value is preferably as large as possible in terms of improvement in retention.

However, there is a tradeoff between decreased write current Ic and increased Δ value with respect to the structure and material of the magnetoresistive element. When the structure and material are employed such that the write current Ic is small, the Δ value is also small. When the structure and material are employed such that the Δ value is large, the write current Ic is also large. In sum, (Ic/Δ value) is, for example, a constant value X. When one of the write current Ic and the Δ value is improved, the other one of the write current Ic and the Δ value is deteriorated.

As described above, it is difficult to realize the decrease in the write current Ic and the increase in the Δ value at the same time.

The present embodiment focuses attention on the temperature dependency of the write current Ic and the value.

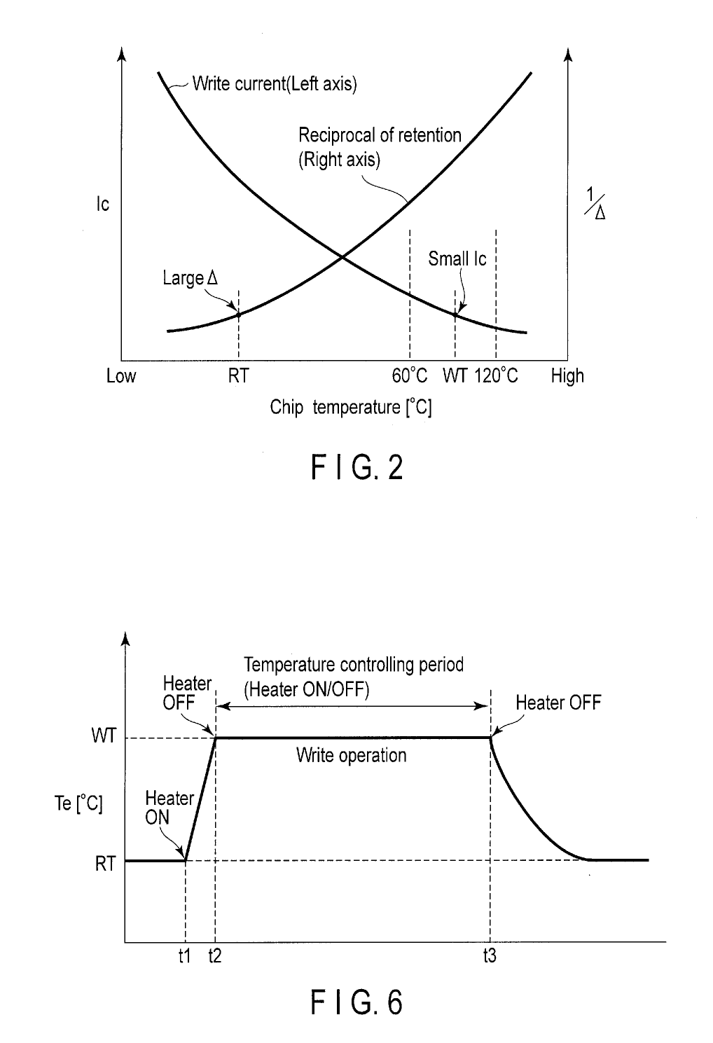

As shown in FIG. 2, the write current Ic and the Δ value are temperature-dependent. When the temperature of the magnetoresistive element (element temperature) is increased, or specifically, when the chip temperature is increased, both the write current Ic and the Δ value are decreased. When the temperature of the magnetoresistive element is decreased, both the write current Ic and the Δ value are increased.

The present embodiment employs the temperature dependency and suggests a technique in which the temperature of the magnetoresistive element during a write operation is higher than the temperature of the magnetoresistive element before the write operation starts or after the write operation has finished.

For example, when the temperature of the magnetoresistive element before the write operation starts or after the write operation has finished is room temperature RT, the temperature of the magnetoresistive element during the write operation is set to a write temperature WT which is higher than room temperature RT.

In this case, for example, the magnetoresistive element is developed such that a large Δ value which can fully satisfy the specification of the magnetic memory is obtained at room temperature RT. In addition, the write temperature WT is set such that a small write current Ic which can fully satisfy the specification of the magnetic memory is obtained. By this development and setup, it is possible to decrease the write current Ic and increase the Δ value at the same time.

For the above reasons, in the present embodiment, the heater 14 and the temperature sensor 15 are provided in the memory cell array 10.

However, the optimal range of the write temperature WT is restricted.

For example, when the optimal range of the write temperature WT is assumed to be 60 to 120° C., feedback control should be conducted such that the temperature of the magnetoresistive element (element temperature) is maintained within the optimal range, for example, at 90° C. (the write temperature WT), during the write operation.

In the present embodiment, a heater driver 16 and a temperature detector 17 are provided outside the memory cell array 10.

The heater driver 16 determines the on/off of the heater 14 in the memory cell array 10. The temperature detector 17 detects the temperature of the magnetoresistive element based on data from the temperature sensor 15.

A control circuit 18 controls the heater driver 16 based on temperature data which is fed back from the temperature detector 17.

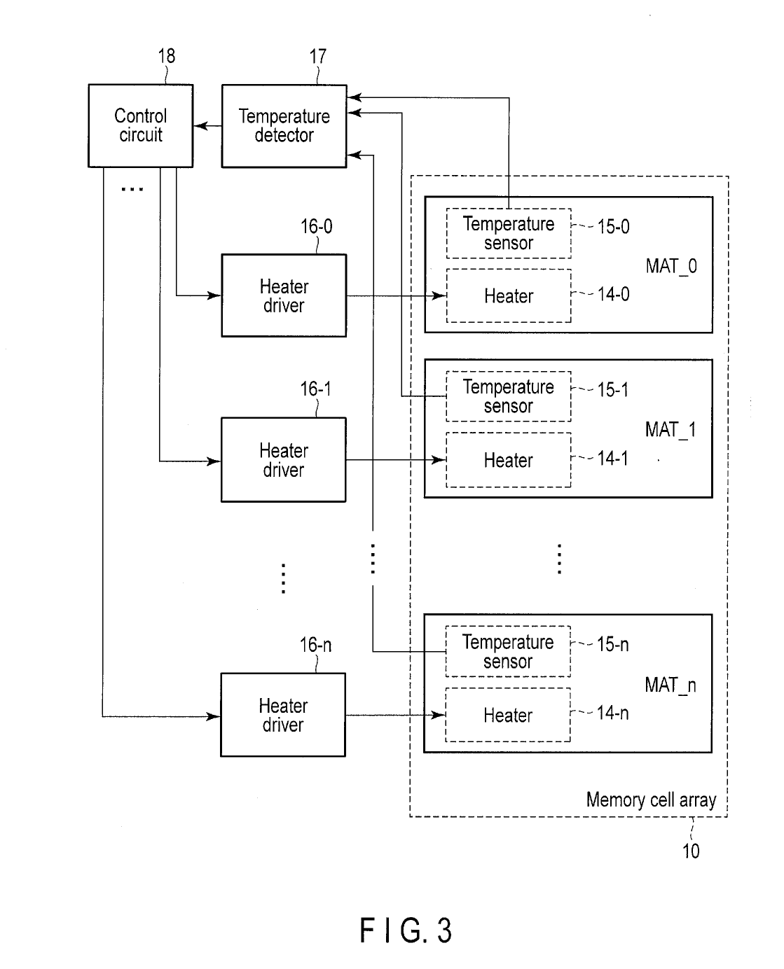

As shown in FIG. 3, the memory cell array 10 may comprise mats (memory blocks) MAT_0, MAT_1, . . . , MAT_n, where n is a natural number greater than or equal to 2. In this case, heater 14-x and temperature sensor 15-x are provided in each mat MAT_x, where x is one of 0, 1, . . . , n.

Heater drivers 16-0, 16-1, . . . , 16-n are preferably provided in association with mats (blocks) MAT_0, MAT_1, . . . , MAT_n.

In this case, the control circuit 18 independently controls the temperature of the magnetoresistive element (element temperature) of each of mats MAT_0, MAT_1, . . . , MAT_n.

### (2) Temperature Control Operation

This specification explains a temperature control operation by the control circuit 18 of FIG. 1 or FIG. 3.

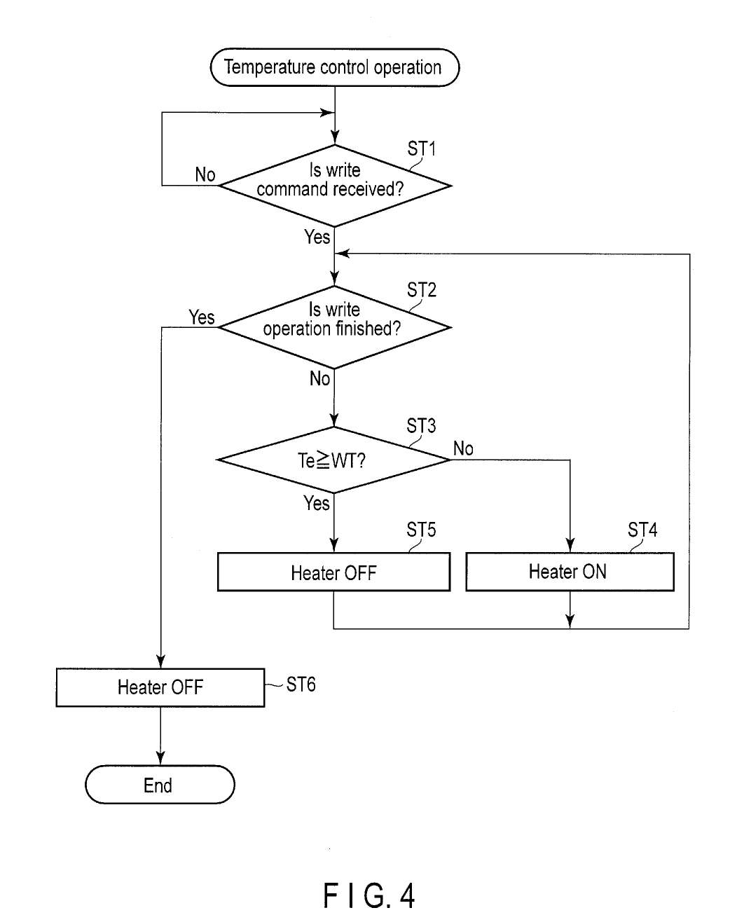

FIG. 4 is a flowchart showing the temperature control operation.

After receiving a write command, the control circuit confirms the magnitude relationship between the temperature of the magnetoresistive element (element temperature) Te and the write temperature WT (steps ST1 to ST3).

For example, when the element temperature Te is lower than the write temperature WT, the control circuit uses the heater driver to turn the heater on and thereby raises the element temperature Te (step ST4). When the element temperature Te is equal to or higher than the write temperature WT, the control circuit uses the heater driver to turn the heater off and thereby lowers the element temperature Te (step ST5).

However, when the element temperature Te is equal to or higher than the write temperature WT, the control circuit does not always have to turn the heater off.

After confirming that the write operation has finished, the control circuit uses the heater driver to turn the heater off and thereby lowers the element temperature Te (step ST6).

As is clear from the flowchart, the temperature control operation is performed when the write command is received. The element temperature Te is set to be equal to or higher than the write temperature WT in advance by the temperature control operation before the write operation is actually started after the write command is received.

In this manner, the actual write operation can be performed at the write temperature WT or a temperature higher than the write temperature WT. Thus, magnetization inversion (0/1-switching) is possible at the write current Ic which is sufficiently small.

### (3) Write Operation

This specification explains the control of the write operation by the control circuit 18 of FIG. 3.

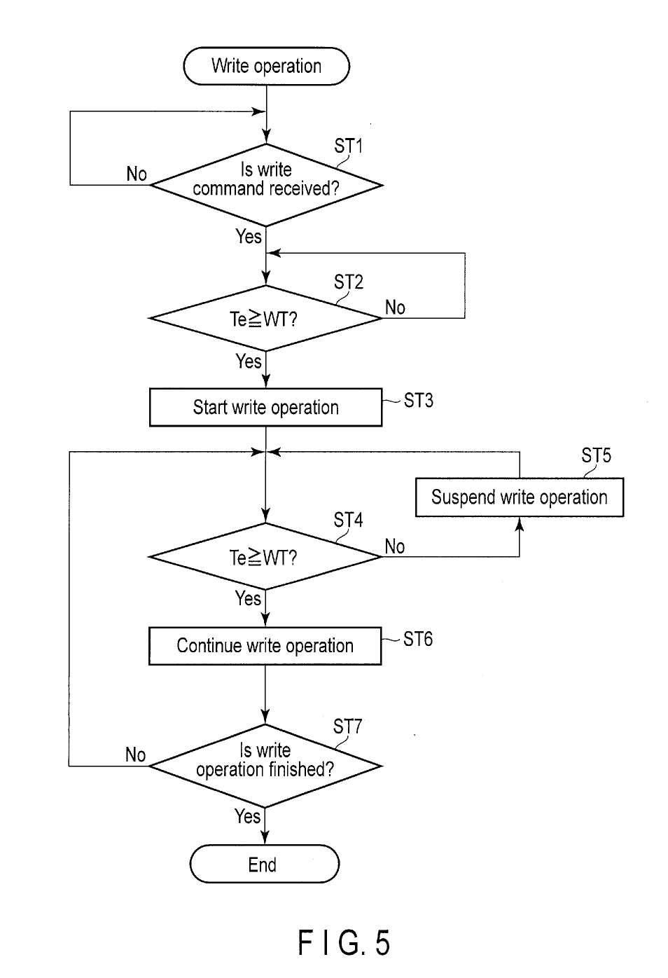

FIG. 5 is a flowchart showing the write operation.

After receiving a write command, the control circuit confirms the magnitude relationship between the temperature of the magnetoresistive element (element temperature) Te and the write temperature WT (steps ST1 and ST2).

When the element temperature Te is equal to or higher than the write temperature WT, the control circuit begins the write operation (step ST3).

The control circuit also confirms the magnitude relationship between the temperature of the magnetoresistive element Te and the write temperature WT (step ST4).

For example, when the element temperature Te is lower than the write temperature WT, the control circuit suspends the write operation (step ST5). When the element temperature Te is equal to or higher than the write temperature WT, the control circuit continues the write operation (step ST6).

When confirming that the write operation has finished, the control circuit finishes the sequence of the write operation (step ST7).

As is clear from the flowchart, for example, the write operation is always performed at the write temperature WT or a temperature higher than the write temperature WT under the temperature control operation shown in FIG. 4.

For example, as shown in FIG. 6, in a case where the write command is received at time t1, the actual write operation is performed from time t2 when a predetermined time has passed after time t1. During the write operation, the write temperature WT or a temperature higher than the write temperature WT is maintained. After time t3 when the write operation has finished, the element temperature Te is returned to room temperature RT.

During the write operation, the temperature is set to the write temperature WT which is higher than room temperature RT. In the other periods, for example, room temperature RT is maintained. Therefore, it is possible to realize both a small write current Ic and a large Δ value.

In a read operation, there is no particular need to set the temperature to WT. Therefore, the read operation can be performed at any time as soon as the controller receives a read command. A read signal amount is determined by the difference between a high-resistance state (anti-parallel state) and a low-resistance state (parallel state). It is advantageous to the read operation when the difference is large. Generally, the difference is large at low temperatures. Therefore, the temperature is preferably low when the read operation is conducted. However, it is unnecessary to restrict the temperature in the read operation if the read signal amount can be sufficiently ensured by the design. Therefore, even if the temperature in the read operation is WT, the read operation can be performed immediately after the write operation as described above.

### (4) Layout of Memory Cell Array

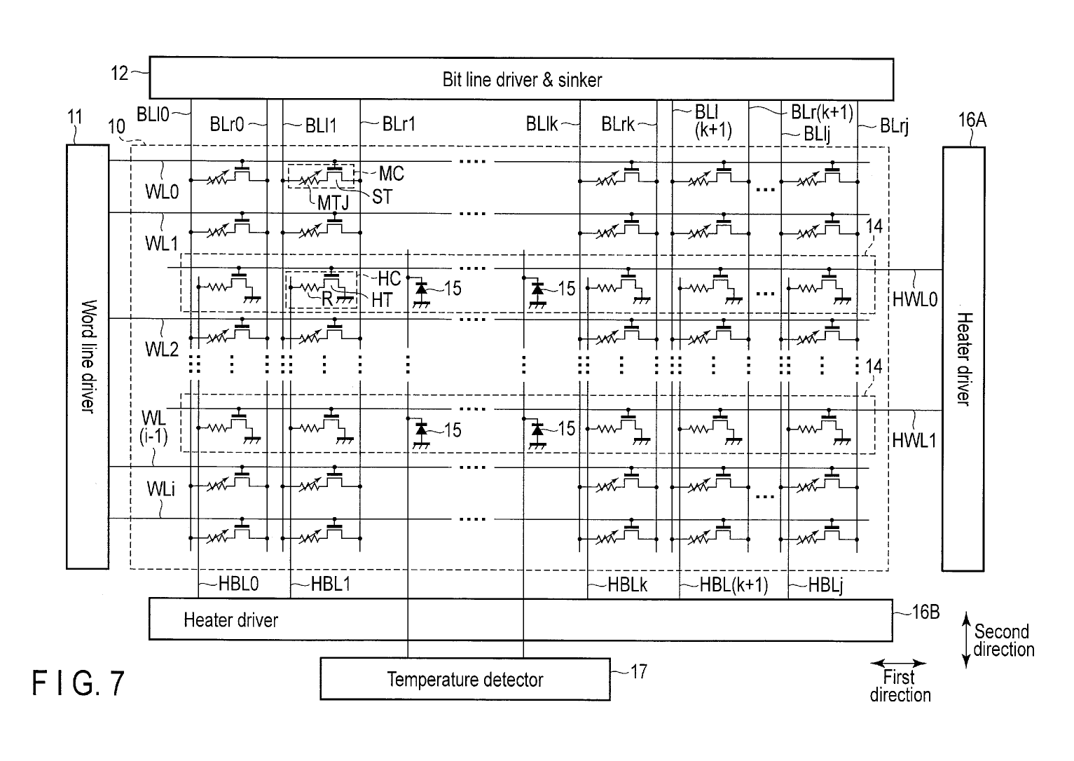

FIG. 7 shows a first example of the layout of the memory cell array.

A memory cell MC comprises a select transistor (FET) and a magnetoresistive element MTJ which are connected in series. A control terminal (gate) of select transistor ST is connected to word line WLi (i=0, 1, 2, . . . ). An end of the memory cell MC is connected to bit line BLlk, and the other end of the memory cell MC is connected to bit line BLrk, where k is 0, 1, . . . , j (j is a natural number).

For example, word lines WL0, WL1, . . . , WLi extend in a first direction, and are connected to the word line driver 11. For example, bit lines BLl0 to BLlj and BLr0 to BLrj extend in a second direction intersecting with the first direction, and are connected to the bit line driver and sinker 12.

The heater 14 comprises, for example, a heater cell HC provided in one row of the memory cell array. The heater cell HC comprises select transistor (FET) HT and a resistive element R which are connected in series.

A control terminal (gate) of select transistor HT is connected to heater word lines HWL0 and HWL1. An end of the heater cell HC is connected to heater bit lines HBL0 and HBL1, and the other end of the heater cell HC is connected to a ground terminal (ground potential).

For example, heater word lines HWL0 and HWL1 extend in the first direction, and are connected to heater driver 16A. For example, heater bit lines HBL0 and HBL1 extend in the second direction, and are connected to heater driver 16B.

For example, the temperature sensor (diode having temperature dependency) 15 is provided in one row of the memory cell array, and is connected to the temperature detector 17 via a conductive line extending in the second direction.

Thus, in this example, the heater 14 and the temperature sensor 15 are provided in one row of the memory cell array. In this structure, it is possible to accurately set the temperature of the magnetoresistive element (element temperature), and produce the heater 14 and the temperature 15 in line with the manufacturing process of the memory cell array.

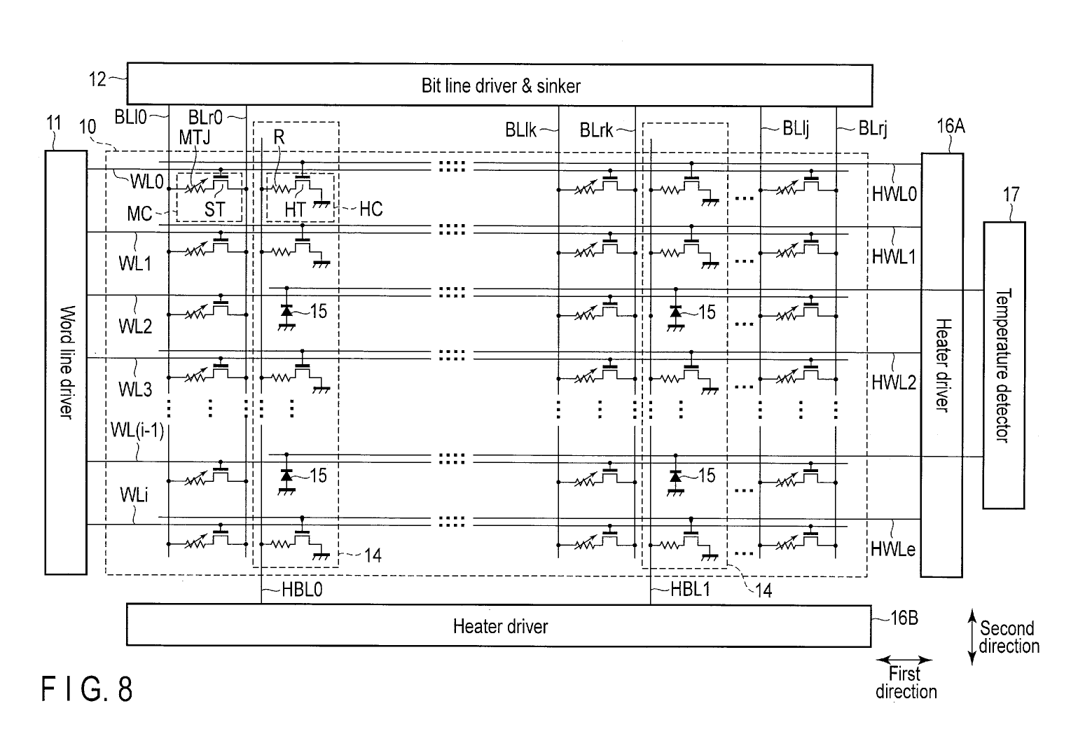

FIG. 8 shows a second example of the layout of the memory cell array.

As the layout of the memory cell MC is the same as the first example shown in FIG. 7, the explanation of the layout is omitted.

The heater 14 comprises, for example, the heater cell HC provided in one column of the memory cell array. The heater cell HC comprises select transistor (FET) HT and the resistive element R which are connected in series.

The control terminal (gate) of select transistor HT is connected to heater word lines HWL0 to HWLe. An end of the heater cell HC is connected to heater bit lines HBL0 and HBL1, and the other end of the heater cell HC is connected to the ground terminal (ground potential).

For example, heater word lines HWL0 to HWLe extend in the first direction, and are connected to heater driver 16A. For example, heater bit lines HBL0 and HBL1 extend in the second direction, and are connected to heater driver 16B.

For example, the temperature sensor (diode having temperature dependency) 15 is provided in one column of the memory cell array, and is connected to the temperature detector 17 via a conductive line extending in the first direction.

Thus, in this example, the heater 14 and the sensor 15 are provided in one column of the memory cell array. In this structure, it is possible to accurately set the temperature of the magnetoresistive element (element temperature), and produce the heater 14 and the temperature sensor 15 in line with the manufacturing process of the memory cell array.

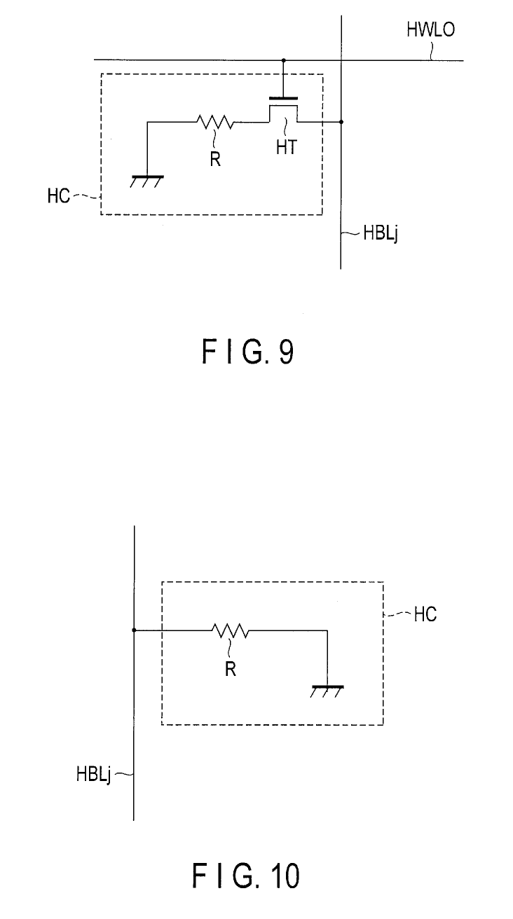

FIG. 9 and FIG. 10 show circuit examples of the heater cell.

As shown in FIG. 9, the heater cell HC may comprise select transistor HT and the resistive element R which are connected in series. As shown in FIG. 10, the heater cell HC may comprise the resistive element R only. In the former case, the structure of the heater cell HC is very similar to the structure of the memory cell MC. Therefore, the former case is preferable to the latter case in terms of manufacturing process.

### (5) Device Structure

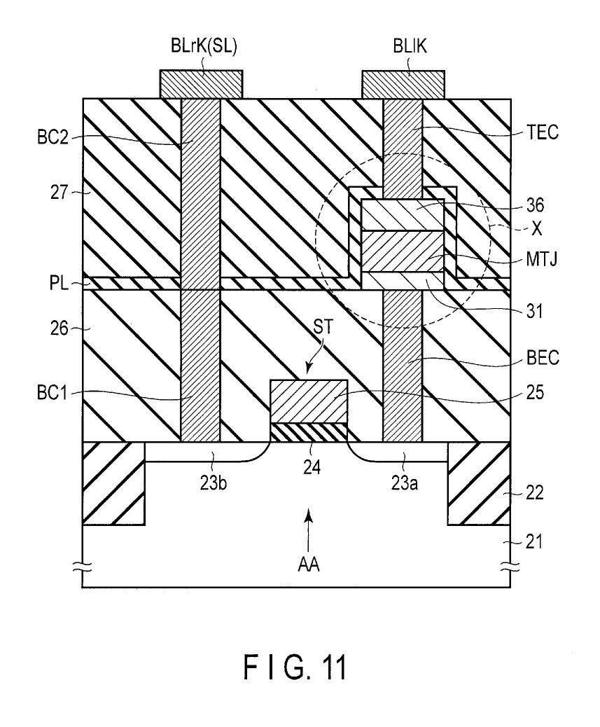

FIG. 11 shows an example of the memory cell of the magnetic memory.

In this example, the memory cell of the magnetic memory comprises select transistor ST and the magnetoresistive element MTJ.

Select transistor ST is provided in an active area AA in a semiconductor substrate 21. The active area AA is surrounded by an element separation insulating layer 22 in the semiconductor substrate 21. In this example, the element separation insulating layer 22 has a shallow-trench-isolation (STI) structure.

Select transistor ST comprises source/drain diffusion layers 23a and 23b in the semiconductor substrate 21, a gate insulating layer 24 on the channel between source/drain diffusion layers 23a and 23b, and a gate electrode 25 on the gate insulating layer 24. The gate electrode 25 functions as a word line.

An interlayer insulating layer (for example, a silicon oxide layer) 26 covers select transistor ST. Contact plugs BEC and BC1 are provided in the interlayer insulating layer 26. The upper surface of the interlayer insulating layer 26 is flat. A lower electrode 31 is provided on the interlayer insulating layer 26.

The lower electrode 31 comprises, for example, one of Al, Be, Mg, Ca, Sr, Ba, Sc, Y, La, Zr and Hf, alloy containing one of Al, Be, Mg, Ca, Sr, Ba, Sc, Y, La, Zr and Hf, or a chemical compound of B and one of Al, Be, Mg, Ca, Sr, Ba, Sc, Y, La, Zr and Hf (for example, HfB, MgAlB, HfAlB, ScAlB, ScHfB and HfMgB).

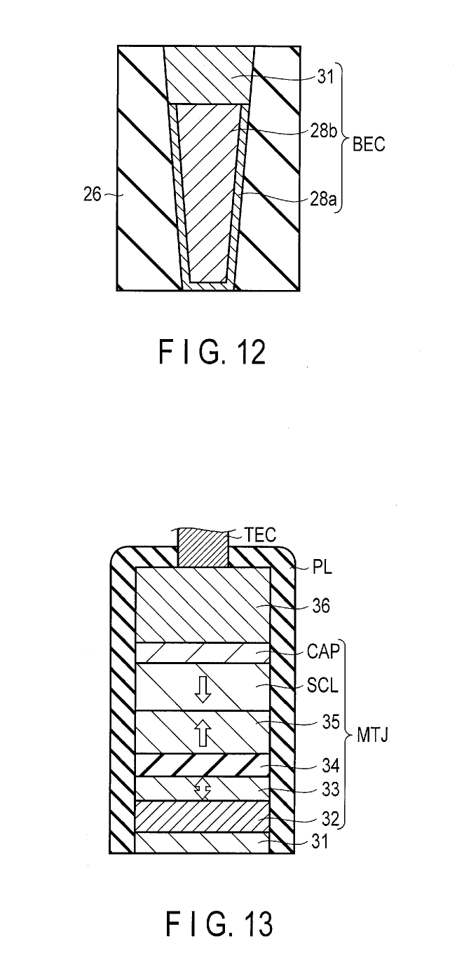

As shown in FIG. 12, the lower electrode 31 may be embedded in a contact hole. For example, when contact plug (bottom electrode contact) BEC comprises a barrier metal 28a and a metal layer 28b, the lower electrode 31 may be connected to contact plug BEC in the contact hole.

The lower electrode 31 is connected to source/drain diffusion layer 23a of select transistor ST via contact plug BEC. Contact plug BC1 is connected to source/drain diffusion layer 23b of select transistor ST.

The magnetoresistive element MTJ is provided on the lower electrode 31. An upper electrode 36 is provided on the magnetoresistive element MTJ. The upper electrode 36 comprises, for example, W, Ta, Ru, Ti, TaN or TiN.

In addition to the function as an electrode, the upper electrode 36 has a function as a mask when the magnetoresistive element MTJ is patterned. The upper electrode 36 has a low electrical resistance, and preferably has a material excellent in diffusion resistance, etching resistance, milling resistance and the like, such as a lamination of Ta/Ru.

A protective insulating layer (for example, a silicon nitride layer) PL covers the sidewalls of the magnetoresistive element MTJ. An interlayer insulating layer (for example, a silicon oxide layer) 27 is provided on the protective insulating layer PL, and covers the magnetoresistive element MTJ. The upper surface of the interlayer insulating layer 27 is flat. Bit lines BLlk and BLrk are provided on the interlayer insulating layer 27.

Bit line BLlk is connected to the upper electrode 16 via contact plug (top electrode contact) TEC. Bit line BLrk is connected to contact plug BC1 via contact plug BC2. Bit line BLrk also functions as a source line SL to which ground potential is applied at the time of the read operation.

FIG. 13 shows an example of the magnetoresistive element MTJ of FIG. 11.

FIG. 13 corresponds to the structure in an area X of FIG. 11.

The magnetoresistive element MTJ comprises a foundation layer 32, a first magnetic layer (memory layer) 33 provided on the foundation layer 32, a nonmagnetic insulating layer (tunnel barrier layer) 34 provided on the first magnetic layer 33, a second magnetic layer (reference layer) 35 provided on the nonmagnetic insulating layer 34, a shift cancel layer (magnetic layer) SCL provided on the second magnetic layer 35, and a cap layer CAP provided on the shift cancel layer SCL.

The foundation layer 32 is provided on the lower electrode 31. The foundation layer 32 is provided to crystallize the magnetoresistive element MTJ. The foundation layer 32 preferably contains, for example, MgO, or a nitrogen compound such as AlN, MgN, ZrN, NbN, SiN and AlTiN.

The first magnetic layer 33 has, for example, a perpendicular and variable magnetization. The second magnetic layer 35 has, for example, a perpendicular and invariable magnetization. The perpendicular direction refers to a direction in which the first and second magnetic layers 33 and 35 are stacked. Invariable magnetization means that the magnetization direction before and after writing is the same. Variable magnetization means that the magnetization direction before writing may change to the opposite direction after writing.

Writing refers to spin transfer writing which applies spin torque to the magnetization of the second magnetic layer 12 by supplying a write current (spin-polarized electron) to the magnetoresistive element.

The first and second magnetic layers 33 and 35 contain Co, Fe, Ni or the like, and comprise, for example, CoFeB, MgFeO or a lamination of CoFeB and MgFeO. The nonmagnetic insulating layer 34 comprises, for example, MgO or AlO. The nonmagnetic insulating layer 34 may be a nitride of, for example, Al, Si, Be, Mg, Ca, Sr, Ba, Sc, Y, La, Zr or Hf.

The shift cancel layer SCL has a magnetization direction opposite to the magnetization direction of the second magnetic layer 35, and has a function of cancelling the shift of magnetization inversion property of the first magnetic layer 33.

The shift cancel layer SCL generates a leakage magnetic field (stray magnetic field) opposite to the leakage magnetic field generated by the second magnetic layer 35. Since these leakage magnetic fields offset each other, it is possible to cancel the shift of magnetization inversion property of the first magnetic layer 33.

For example, the shift cancel layer SCL preferably has a structure of [Co/Pt]n, in which Co and Pt layers are stacked n times.

The cap layer CAP functions as a buffer layer which prevents a reaction between the shift cancel layer SCL and the upper electrode 36. A cap layer 19 comprises, for example, Pt, W, Ta and Ru.

In this example, the upper and lower relationship between the first magnetic layer 33 and the second magnetic layer 35 is not particularly limited. For example, in a manner different from this example, the first magnetic layer 33 may be provided above the second magnetic layer 35.

In this example, a perpendicular magnetization magnetoresistive element is employed. However, instead of it, an in-plane magnetization magnetoresistive element may be employed.

Since the other structures are the same as the structures of the memory cell of the magnetic memory of FIG. 11, elements identical to those disclosed in FIG. 11 are denoted by the same reference numbers. Thus, the explanation of such elements is omitted.

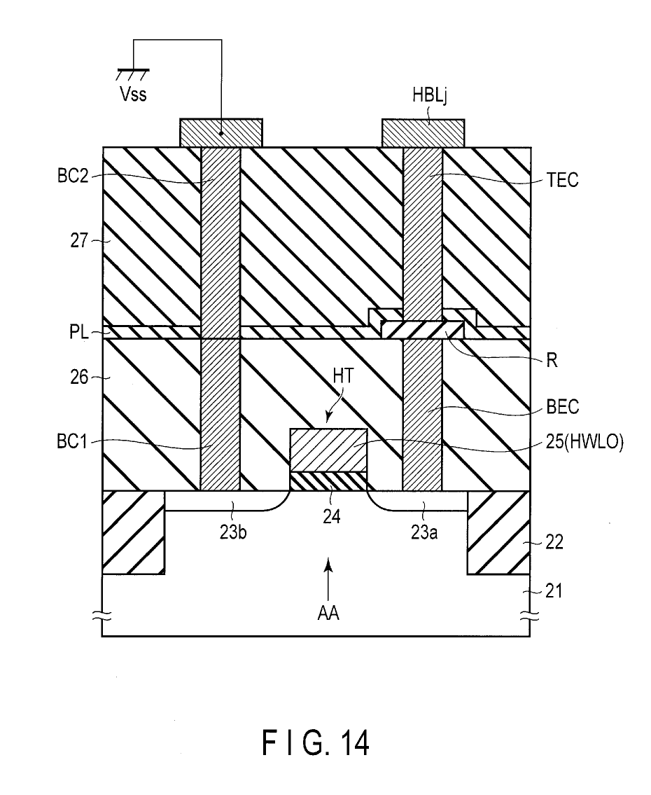

FIG. 14 shows a structural example of the heater cell.

The heater cell has a feature in respect that its structure is very similar to the structure of the memory cell of the magnetic memory of FIG. 11. To clarify how the heater cell corresponds to the memory cell, in FIG. 14, portions corresponding to the memory cell of FIG. 11 are indicated by the same reference numbers.

The heater cell comprises select transistor HT and the resistive element R.

Select transistor HT is provided in the active area AA in the semiconductor substrate 21. The active area AA is surrounded by the element separation insulating layer 22 in the semiconductor substrate 21. In this example, the element separation insulating layer 22 has the STI structure.

Select transistor HT comprises source/drain diffusion layers 23a and 23b in the semiconductor substrate 21, the gate insulating layer 24 on the channel between source/drain diffusion layers 23a and 23b, and the gate electrode 25 on the gate insulating layer 24. The gate electrode 25 functions as heater word line HWL0.

The interlayer insulating layer (for example, a silicon oxide layer) 26 covers select transistor HT. Contact plugs BEC and BC1 are provided in the interlayer insulating layer 26. The upper surface of the interlayer insulating layer 26 is flat. The resistive element R is provided on the interlayer insulating layer 26, and is connected to contact plug BEC.

The resistive element R comprises an oxide of, for example, W, Ta, Ru and Ti.

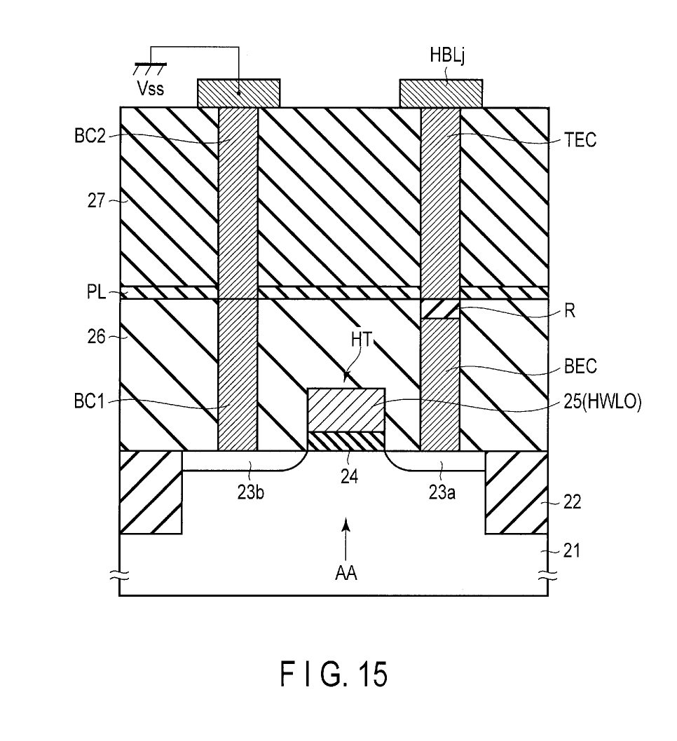

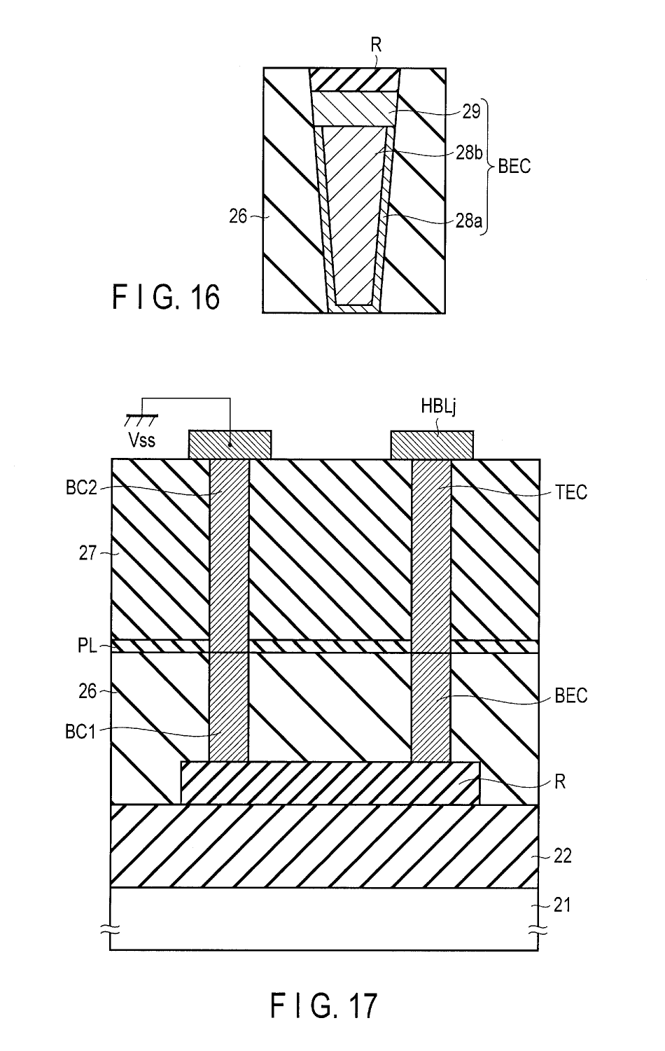

As shown in FIG. 15, the resistive element R may be embedded in the contact hole. For example, as shown in FIG. 16, when contact plug BEC comprises the barrier metal 28a, the metal layer 28b, and further, a metal layer 29 on the metal layer 28b, the resistive element R may be provided on the metal layer 29 as an oxide of the metal layer 29 in the contact hole.

The resistive element R is connected to source/drain diffusion layer 23a of select transistor HT via contact plug BEC. Contact plug BC1 is connected to source/drain diffusion layer 23b of select transistor HT.

The protective insulating layer (for example, a silicon nitride layer) PL is provided on the interlayer insulating layer 26. The interlayer insulating layer (for example, a silicon oxide layer) 27 is provided on the protective insulating layer PL. The upper surface of the interlayer insulating layer 27 is flat. Heater bit line HBLj is provided on the interlayer insulating layer 27. Heater bit line HBLj is connected to the resistive element R via contact plug TEC. Contact plug BC2 is connected to a ground terminal Vss.

FIG. 17 shows a modification example of the heater cell.

The heater cell has a feature in respect that the resistive element R is a polysilicon resistive element. In this case, the resistive element R is provided on the element separation insulating layer 22. For example, the resistive element R can be formed at the same time as the gate electrode 25 of select transistor ST of the memory cell of FIG. 11.

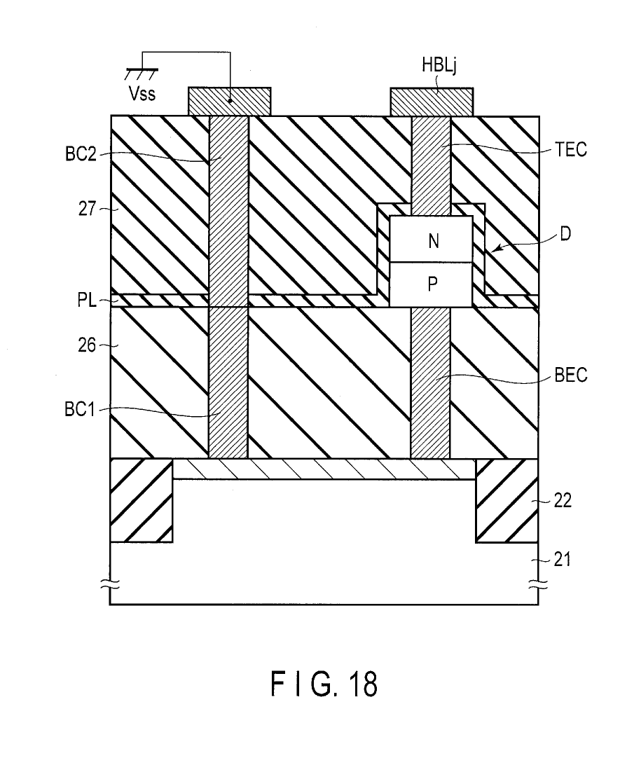

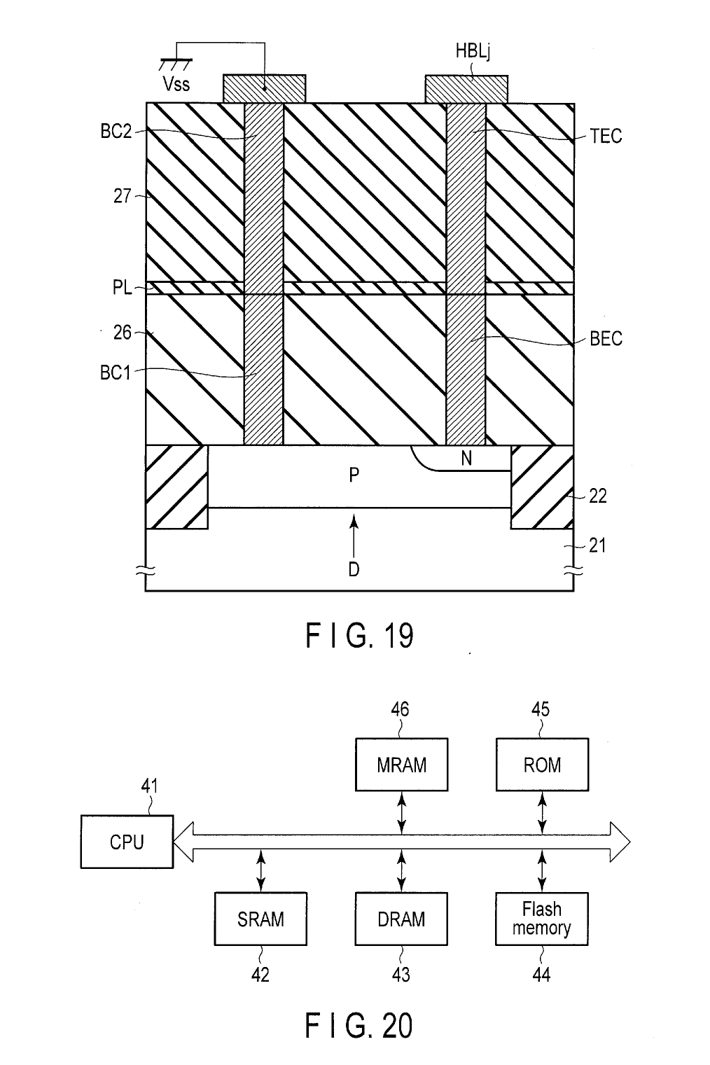

FIG. 18 and FIG. 19 show structural examples of the diode as a temperature sensor.

The diode D as a temperature sensor comprises, for example, a PN junction diode. The diode D may be, for example, a PIN diode, a SIM diode or a MIM diode. The diode D may be provided above the semiconductor substrate 21, for example, on the interlayer insulating layer 26 as shown in FIG. 18, or may be provided in the semiconductor substrate 21 as shown in FIG. 19.

### 2. Application Example

This specification explains an application example of the above-described magnetic memory.

FIG. 20 shows an example of a memory system in a processor.

A CPU 41 controls an SRAM 42, a DRAM 43, a flash memory 44, a ROM 45 and a magnetic random access memory (MRAM) 46.

The above-described magnetic memory is applied to the MRAM 46.

The MRAM 46 can be used in place of the SRAM 42, the DRAM 43, the flash memory 44 or the ROM 45. Accordingly, at least one of the SRAM 42, the DRAM 43, the flash memory 44 and the ROM 45 may be omitted.

The MRAM 46 can be used as a nonvolatile cache (for example, an L2 cache).

### 3. Conclusion

In the present embodiment, it is possible to improve the tradeoff between the reduction in the write current which is necessary for the magnetization inversion of the memory layer and the magnetization stability of the memory layer after writing.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic memory comprising:
a memory cell array including magnetoresistive elements;
a heater and a temperature sensor provided in the memory cell array;
a heater driver which drives the heater;
a temperature detector which detects a first temperature sensed by the temperature sensor; and
a control circuit which controls the heater driver based on the first temperature.

2. The memory of claim 1, wherein
the heater includes a resistive element.

3. The memory of claim 2, wherein
the resistive element has a resistance between 1 kΩ and 100 kΩ.

4. The memory of claim 1, wherein
the temperature sensor includes a diode with temperature dependency.

5. The memory of claim 1, wherein
the memory cell array includes memory blocks, and each of the memory blocks includes the heater and the temperature sensor.

6. The memory of claim 5, wherein
the control circuit controls the first temperature of each of the memory blocks independently.

7. The memory of claim 1, wherein
the control circuit turns the heater on using the heater driver when the first temperature is lower than a second temperature after receiving a write command.

8. The memory of claim 7, wherein
the control circuit starts a write operation when the first temperature is higher than the second temperature.

9. The memory of claim 8, wherein
the control circuit suspends a write operation when the first temperature is lower than the second temperature.

10. The memory of claim 8, wherein
the control circuit turns the heater off using the heater driver when the write operation is finished.

11. The memory of claim 1, wherein
the heater includes a resistive element which is provided in one row or one column of the memory cell array.

12. The memory of claim 11, wherein
the heater includes a select transistor which selects the resistive element, the resistive element being provided above the select transistor.

13. The memory of claim 12, further comprising:
a contact plug in a contact hole connected to the select transistor, the resistive element being provided in the contact hole and being connected to the contact plug.

14. The memory of claim 13, wherein
the contact plug includes a metal layer, and the resistive element includes an oxide of the metal layer.

15. The memory of claim 1, wherein
the temperature sensor includes a diode with temperature dependency which is provided in one row or one column of the memory cell array.

16. The memory of claim 1, wherein
the memory cell array and the diode are provided above a semiconductor substrate.

17. The memory of claim 1, wherein
the memory cell array is provided above a semiconductor substrate and the diode is provided in the semiconductor substrate.

18. The memory of claim 1, wherein
each of the magnetoresistive elements includes:
a first magnetic layer having an invariable magnetization;
a second magnetic layer having a variable magnetization; and
a nonmagnetic insulating layer between the first and second magnetic layers.

19. The memory of claim 18, wherein
each of the first and second magnetic layers has a remanent magnetization in a vertical direction in which the first and second magnetic layers are stacked.

20. The memory of claim 18, wherein
a magnetization direction of the second magnetic layer is changed by a write current which flows between the first and second magnetic layers.
